(19) United States
(12) Patent Application Publication
(10) Pub. No.: US 2004/0195937 A1
(43) Pub. Date: Oct. 7, 2004

(54) Film bulk acoustic resonator and film bulk acoustic resonator circuit

(76) Inventors: Shogo Matsubara, Kasuga-shi (JP); Hideaki Horio, Kasuya-gun (JP); Yosuke Mizuyama, Munakata-shi (JP)

Correspondence Address: WENDEROTH, LIND & PONACK, L.L.P., 2033 K STREET N. W., SUITE 800, WASHINGTON, DC, 20006-1021, US

(21) Appl. No.: 10/813,298

(22) Filed: Mar. 31, 2004

(30) Foreign Application Priority Data
Apr. 1, 2003 (JP) P. 2003-097900

(51) Int. Cl. H01L 41/047

(52) U.S. Cl. 310/320

(57) ABSTRACT

In a film bulk acoustic resonator, a multi-layered member is placed on a substrate. The multi-layered member has: a common electrode; a piezoelectric layer formed on the common electrode; a first electrode which is formed on the piezoelectric layer, and which is used for a resonator; a second electrode which surrounds the edge of the first electrode with forming a gap therebetween, and which is used for a spurious suppressing element; a first wiring through which an electric power is supplied to the first electrode; and a second wiring through which an electric power is supplied to the second electrode. In the film bulk acoustic resonator, the piezoelectric layer includes a ferroelectric film, and a polarization state of the ferroelectric film corresponding to the resonator is different from a polarization state of the ferroelectric film corresponding to the spurious suppressing element.

### BACKGROUND OF THE INVENTION

The present invention relates to a film bulk acoustic resonator which is an electronic component to be used in a radio high-frequency circuit, and also to a film bulk acoustic resonator circuit.

One type of mobile telephones which is becoming increasingly popular is PCS (Personal Communications System) which uses Code Division Multiple Access (hereinafter, abbreviated to CDMA) system (hereinafter, such PCS is referred to as CDMA-PCS). A CDMA-PCS device operates in a frequency band at about 1,900 MHz, and particularly strict requirements are imposed on the performance of a duplexer. The guard band between spectrum portions assigned to transmitted and received signals is only about 1% of the carrier frequency, that is, 20 MHz. The bandwidth of the spectrum portion allocated to transmitted and received signals is about 3% of the carrier frequency, that is, 60 MHz. This means that band-pass filters for transmission and reception are required to have an extremely sharp characteristics (roll-off). Moreover, it is necessary to provide a duplexer having filter characteristics which are sufficiently steep to enable the duplexer to be used in applications such as a CDMA-PCS device in which a power level exceeding 1 watt does not impair the reliability of the duplexer or the long-term stability of the filter characteristics.

By contrast, a duplexer has been proposed which is substantially smaller than a conventional duplexer based on a ceramic filter or a SAW filter, and which uses a film bulk acoustic resonator that can keep the production cost low (for example, U.S. Pat. No. 6,262,637).

A film bulk acoustic resonator (FBAR) is a thin film acoustic device which operates in response to an electric signal, and which can resonate at a high frequency with respect to the microwave range, for example, 0.5 to 5 GHz. A conventional film bulk acoustic resonator has a piezoelectric film between first and second electrodes which apply an electric field to the piezoelectric film. The piezoelectric film is made of a piezoelectric crystalline material such as zinc oxide, aluminum nitride (AlN), or another piezoelectric crystalline material which exhibits a piezoelectric effect. For example, the piezoelectric effect occurs when the piezoelectric material expands or contracts in response to an electric field applied to the whole piezoelectric material by the first and second electrodes, or when charges or currents are produced in response to mechanical stress or tension applied to the piezoelectric material. The mechanical resonance frequency of a piezoelectric film having a uniform thickness is obtained by dividing the acoustic velocity (v) by two times the film thickness (t) or fr=v/2t. The frequency of a high-frequency source matches the mechanical resonance frequency of the piezoelectric film. When an alternating electric field of a variable frequency is applied to a piezoelectric film by using the high-frequency source, therefore, very large mechanical oscillations occur in the piezoelectric film. Because of the large mechanical oscillations, the piezoelectric material produces the maximum amount of current at the resonance frequency. A piezoelectric film produces different amounts of current depending on the level of the frequency. Therefore, a piezoelectric film is useful as an element in an electrical filter, an oscillator, or a frequency control circuit.

In order to enable the resonator to resonate at a usual RF frequency such as 2 GHz, an aluminum nitride film has typically a thickness of 2.5 microns, and electrodes have a thickness of about 300 microns optimumly suitable to a 50-ohm circuit. Therefore, the ratio of the material thickness to the lateral dimension is small, and the sound energy is not efficiently restricted in a lateral direction. Harmful interactions between different types of acoustic waves (those of different modes) and the edge of the resonator occur, and large fields at the edge of the resonator may create unwanted oscillations in the resonator, thereby generating spurious signals. These phenomena remove energy from the desired oscillation and degrade the quality of the resonator.

By contrast, a method has been proposed in which the thickness of a middle portion of a resonator is increased to enhance the resonant mode of the middle portion of the resonator, thereby preventing part of energy from being converted to unwanted oscillations by the edge of the resonator (for example, U.S. Pat. No. 6,420,202).

However, it is very difficult to accurately control the thickness of a piezoelectric thin film of a resonator in a plane. In the conventional art, it is proposed to employ a method of forming an AlN film having a dome-like shape by the photolithography technique. In the method, however, the film thickness is continuously changed. Therefore, the method has problems in that the insertion loss is increased, that the resulting band width is narrow, and that the resonance frequency is dispersed.

A high-frequency piezoelectric oscillator for a 150-MHz band has been proposed in which, in order to suppress spurious signals, first electrodes for excitation are formed respectively on the surfaces of a piezoelectric substrate to be opposed to each other, a second electrode surrounds the periphery of one of the first electrodes via a gap, and the material of the first electrodes is different from that of the second electrode (for example, U.S. publication 2002-0030424A1).

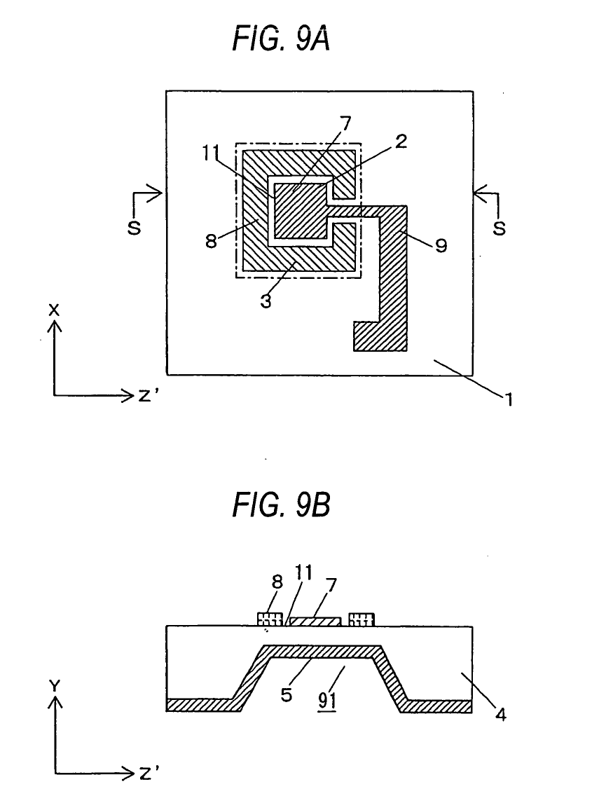

FIG. 9A is a plan view showing the configuration of a conventional spurious suppression type piezoelectric oscillator, and FIG. 9B is a section view taken along the line S-S. A first electrode (excitation electrode) 7 is placed on a flat face side of a substrate 4 in which one face is recessed, and which is made of quartz. A lead electrode 9 elongates from the electrode 7 toward an end portion of the substrate 4. A second electrode 8 is disposed so as to surround the edge of the first electrode 7 via a gap 11. The size of the electrode 8 is substantially equal to that of a recess 91 formed in the substrate 4. A common electrode (excitation electrode) 5 is formed on the side of the recess. The cut-off frequencies of the first electrode 7, the gap 11, and the second electrode 8 are f1, f2, and f3, respectively. The film thicknesses of the electrodes are set so that the magnitude relationship of the cut-off frequencies is f1<f3<f2. As a result, it is possible to provide an AT-cut high-frequency quartz oscillator in which spurious is less generated.

The technique disclosed in U.S. publication 2002-0030424A1 is characterized in that the material of the first electrode (excitation electrode) 7 is different from that of the second electrode 8. More specifically, the density of the second electrode 8 is smaller than that of the first electrode 7. In order to effectively suppress spurious in the high-frequency quartz oscillator for a 150-MHz band, in the case where gold is used as the materials of the both electrodes, for example, the film thickness of the second electrode must be smaller than that of the first electrode by several nm. In order to realize the film thickness difference, moreover, the accuracy of film growth must be as high as about 10% of the film thickness difference. The film growth accuracy is higher than the control limit of an evaporation apparatus or a sputtering apparatus which is usually employed. When a material which is smaller in density than that of the first electrode is used in the second electrode, the film thickness control can be easily conducted.

The above-described measure can be applied also to a film bulk acoustic resonator for a 2 GHz or higher band. As compared with a resonator for 150 MHz, the mass load (acoustic impedance) of an electrode exerts a very larger influence, and hence it is difficult to control the characteristics of the film bulk acoustic resonator by means of the materials and thicknesses of electrodes, thereby causing a problem in that characteristics in mass-produced resonators are largely dispersed. When electrodes of different kinds are to be formed by a thin film forming process, film growing steps and photolithography steps are correspondingly increased in number, and therefore another problem in that the production cost is increased arises.

In the conventional techniques, there are problems such as that characteristics in mass production are largely dispersed, that process steps are complicated, and that the insertion loss is increased.

### SUMMARY OF THE INVENTION

The invention has been conducted in view of these problems. It is an object of the invention to provide a film bulk acoustic resonator and a film bulk acoustic resonator circuit in which unevenness of characteristics in mass production are less.

In order to attain the object, according to the invention, a film bulk acoustic resonator comprises: a piezoelectric element including a ferroelectric film; a first electrode which is disposed on a first surface of the piezoelectric element; a second electrode which is disposed on the first surface, which is electrically insulated from the first electrode, and which is disposed to extend along at least a part of an edge of the first electrode; a third electrode which is disposed on a second surface opposite to the first surface of the piezoelectric element, and which is opposed to the first and second electrodes across the piezoelectric element; a first wiring through which an electric power is supplied to the first electrode; and a second wiring through which an electric power is supplied to the second electrode, wherein a first region of the ferroelectric film which is interposed between the first and third electrodes has a first polarization state, and a second region of the ferroelectric film which is interposed between the second and third electrodes has a second polarization state that is different from the first polarization state. An acoustic impedance of a ferroelectric film largely depends on the direction and magnitude of polarization. When the spontaneous polarization of the ferroelectric film is controlled, therefore, the acoustic impedances of the piezoelectric element in the first and second regions can be more easily controlled than that in the conventional art. As a result, it is possible to provide a film bulk acoustic resonator which has excellent reflective properties and a stable effective band width, at a low cost with high reproducibility.

According to another aspect of the invention, a film bulk acoustic resonator in which in which a multi-layered member is placed on a substrate, the multi-layered member comprising: a common electrode; a piezoelectric layer formed on the common electrode; a first electrode which is formed on the piezoelectric layer, and which is used for a resonator; a second electrode which surrounds an edge of the first electrode with forming a gap therebetween, and which is used for a spurious suppressing element; a first wiring through which an electric power is supplied to the first electrode; and a second wiring through which an electric power is supplied to the second electrode, wherein the piezoelectric layer includes a ferroelectric film, and a polarization state of the ferroelectric film corresponding to the resonator is different from a polarization state of the ferroelectric film corresponding to the spurious suppressing element. Therefore, the spontaneous polarization state of the ferroelectric film can be controlled, and hence the acoustic impedance of the piezoelectric element in the first and second regions can be more easily controlled than that in the conventional art. As a result, it is possible to provide a film bulk acoustic resonator which has excellent reflective properties and a stable effective band width, at a low cost with high reproducibility. After the multi-layered member is formed on a certain substrate the multi-layered member can be transferred onto another substrate via an adhesive agent. Therefore, an arbitrary substrate can be used, so that the production steps can be simplified and the cost of the substrate can be lowered.

### DETAILED DESCRIPTION OF THE DRAWINGS

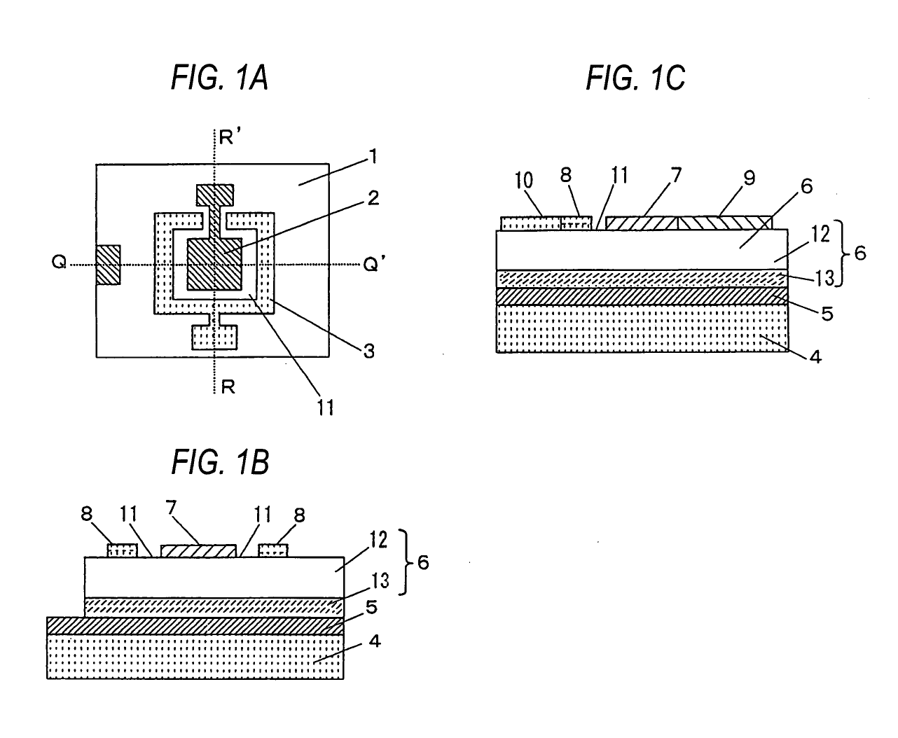

FIG. 1A is a plan view showing a resonator of an embodiment of the invention.

FIG. 1B is a section view taken along the line Q-Q′ of FIG. 1A.

FIG. 1C is a section view taken along the line R-R′ of FIG. 1A.

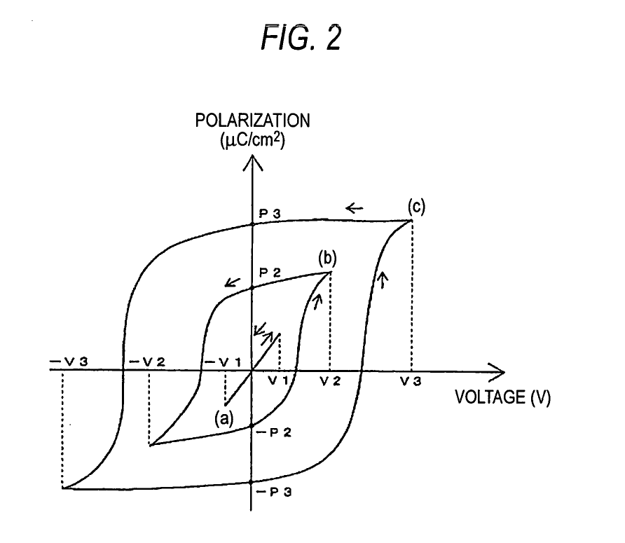

FIG. 2 is a view which shows polarization-voltage characteristics of a ferroelectric film, and in which (a) shows the characteristics in the case where the maximum voltage V1 to be applied is lower than the coercive voltage, (b) shows the characteristics in the case where the maximum voltage V2 is higher than the coercive voltage, and (c) shows the characteristics in the case where the maximum voltage V3 is higher than the voltage V2.

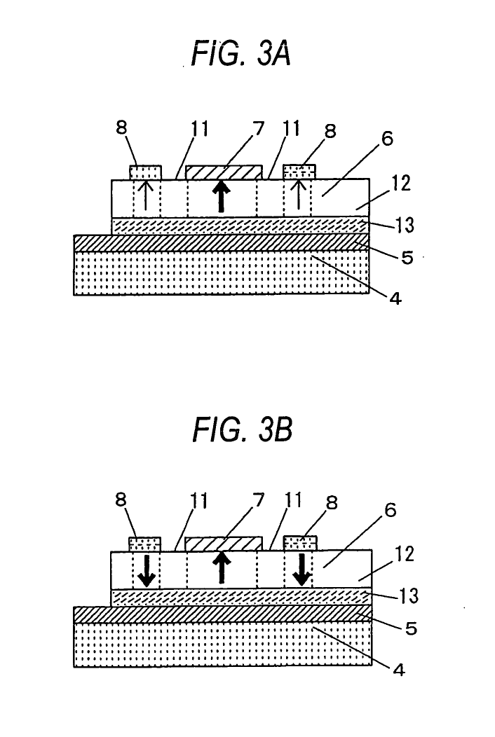

FIG. 3 is a view showing polarization states of the ferroelectric film.

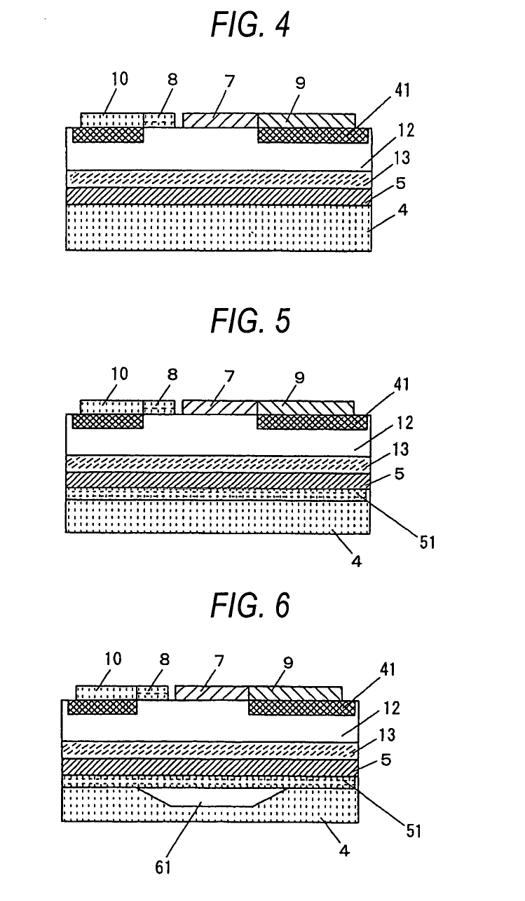

FIG. 4 is a view showing an embodiment of the invention.

FIG. 5 is a view showing an embodiment of the invention.

FIG. 6 is a view showing an embodiment of the invention.

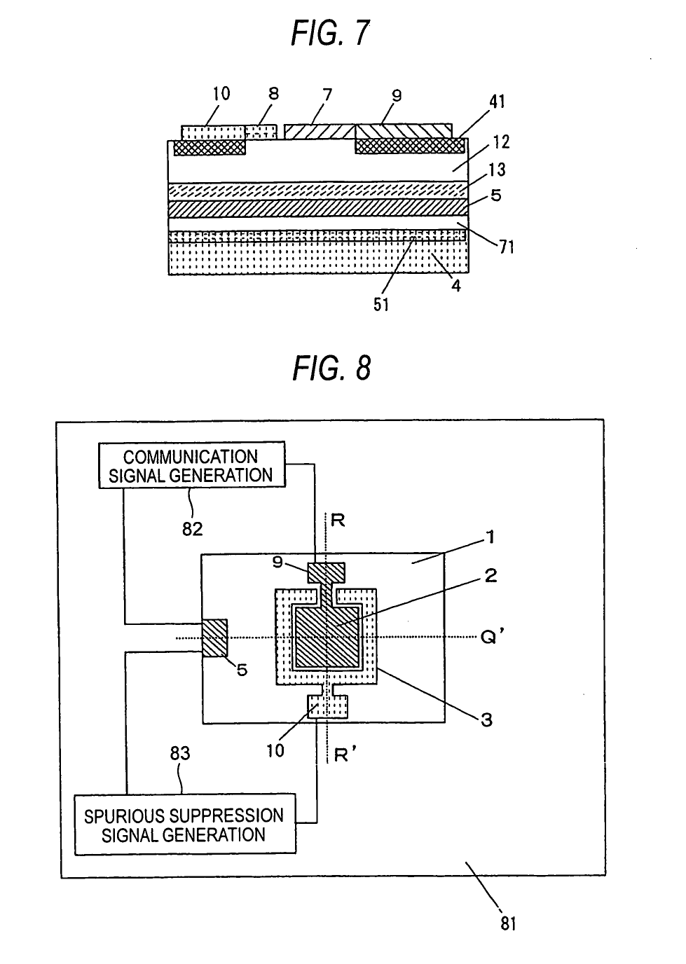

FIG. 7 is a view showing an embodiment of the invention.

FIG. 8 is a view showing an embodiment of the invention.

FIG. 9A is a plan view showing the configuration of a conventional spurious suppression type piezoelectric oscillator, and

FIG. 9B is a section view taken along the line S-S.

### DETAILED DESCRIPTION OF THE DRAWINGS

Hereinafter, embodiments of the invention will be described with reference to the accompanying drawings. In several drawings, identical components are denoted by the same reference numerals.

### First Embodiment

FIG. 1A is a plan view showing a resonator of a first embodiment of the invention, FIG. 1B is a section view taken along the line Q-Q′, and FIG. 1C is a section view taken along the line R-R′. The film bulk acoustic resonator 1 of the embodiment of the invention has a resonator 2 and a spurious suppressing element 3 which is placed around the resonator via a gap 11, and is formed on a substrate 4. The resonator 2 has a structure in which a common electrode 5, a piezoelectric layer 6, and a first electrode 7 are sequentially stacked. The spurious suppressing element 3 has a structure in which the common electrode 5, the piezoelectric layer 6, and a second electrode 8 are sequentially stacked. In order to supply an electric power to the resonator 2, a first wiring 9 is connected to the first electrode 7, and, in order to supply an electric power to the spurious suppressing element 3, a second wiring 10 is connected to the second electrode 8. The first electrode 7, the gap 11, and the second electrode 8 have cut-off frequencies f1, f2, and f3, respectively. The acoustic impedance of the piezoelectric layer 6 is set by the portion of the resonator 2 and that of the spurious suppressing element so as to attain the magnitude relationship of f1<f3<f2, whereby a film bulk acoustic resonator in which spurious is less generated can be provided.

The piezoelectric layer 6 includes a ferroelectric film 12. A film of a solid solution of PbTiO₃—PbZrO₃ (hereinafter, referred to as PZT) which is typical as a ferroelectric film may be used. More preferably, a PZT film which is preferentially oriented in (001) orientation may be used.

In the case where a PZT film is used as the ferroelectric film 12, the piezoelectric layer 6 may further include a temperature compensating layer 13. As the temperature compensating layer 13, strontium titanate or a solid solution of strontium titanate and barium titanate is used. The layer is stacked with the PZT film. The temperature compensating layer 13 has a function of lowering temperature characteristics of the dielectric constant and the Young's modulus of the piezoelectric layer 6.

Referring to the figure, the common electrode 5 and the piezoelectric layer 6 are shared by the resonator 2 and the spurious suppressing element 3. Alternatively, each of the common electrode and the piezoelectric layer may be dividedly formed so that the resulting divided components are used individually for the resonator and the spurious suppressing element, or a groove or the like may be formed so that each of them is used semi-individually. The division can be easily conducted by the photolithography technique and the thin film processing technique. Specifically, the common electrode 5 may be divided into partial electrodes which are electrically insulated from each other, and the partial electrodes may be disposed so as to be opposed respectively to the first electrode 7 and the second electrode 8. The piezoelectric layer 6 may be dividedly formed so as to correspond to the divided shape of the common electrode 5.

The first and second electrodes 7 and 8, and the first and second wirings 9 and 10 are formed by using the same conductive film. Alternatively, they may be formed by conductive films of different kinds, respectively. The first and second electrodes 7 and 8 largely affect the oscillation characteristics of the resonator 2 and the spurious suppressing element 3, and hence consideration must be given to their acoustic impedances. By contrast, the first and second wirings 9 and 10 are requested to have a low wiring resistance and adequacy to wire bonding and bonding to an anisotropic conductive film. As described above, the electrodes and the wirings are often requested to have different performances, and hence the material of a conductive film is suitably selected so as to match with the requested performance.

The embodiment is characterized in that the piezoelectric layer 6 includes the ferroelectric film 12, and more specifically that the spontaneous polarization state of the ferroelectric film in the portion of the resonator 2 is different from that in the spurious suppressing element 3. When an AC voltage is applied to a non-polarized ferroelectric thin film to polarize the film, for example, the polarization-voltage characteristics shown in FIG. 2 are obtained depending on the applied voltage. In the figure, (a) shows the case where the maximum voltage V1 to be applied is lower than the coercive voltage Vc, (b) the case where the maximum voltage V2 is higher than the coercive voltage Vc, and (c) the case where the maximum voltage V3 is higher than the voltage V2. A ferroelectric thin film has a feature that, in a non-polarized state, the polarization-voltage curve is a straight line having no hysteresis, and, when a voltage which is higher than the coercive voltage is applied, the polarization-voltage curve exhibits hysteresis so that the film has a spontaneous polarization amount P2 or −P2 even when the voltage is returned to zero. When a higher voltage is applied, a larger spontaneous polarization amount P3 or −P3 is obtained. However, there is a saturation value, and the spontaneous polarization does not exceed the saturation value. As a result of the polarization process, polarization vectors of the ferroelectric thin film are oriented so as to be maximum in the voltage application direction. When the applied voltage is made higher, crystal grains rotate so that the polarization axes of the crystal grains coincide with the voltage application direction. Usually, the acoustic impedance of a ferroelectric thin film exhibits a crystal anisotropy, and the Young's modulus in the polarization axis direction is small. Therefore, a ferroelectric thin film has characteristics that the acoustic impedance in the polarization axis direction is small. Namely, the acoustic impedance can be controlled by setting the spontaneous polarization states of the ferroelectric film in the portions of the resonator 2 and the spurious suppressing element 3 to be different from each other. According to the invention, the acoustic impedance can be controlled by the level of the applied voltage and the time. This is very easier than the control based on the thickness of a piezoelectric film or an electrode film.

A spontaneous polarization state is indicated by a spontaneous polarization amount such as P1 and P2 shown in FIG. 2. When the spontaneous polarization amount of the ferroelectric film in the portion of the resonator 2 is indicated by Ps1 and that in the portion of the spurious suppressing element 3 is indicated by Ps2, the relationship of f1<f3<f2 can be attained by controlling the amounts so as to be Ps1>Ps2.

With respect to the polarity of the spontaneous polarization of the ferroelectric film, the portion of the resonator 2 is inverted to that of the spurious suppressing element 3, whereby the difference between the acoustic impedances of the resonator 2 and the spurious suppressing element 3 can be further increased. Although the physical reason of this phenomenon is not clearly known, it seems that the ferroelectric film has one of compression stress or tensile stress in the thickness direction and the anisotropy of internal stress relates to the phenomenon. Usually, such a film has anisotropic internal stresses due to physical mismatch of film growth conditions and a substrate, and it is substantially impossible to completely eliminate such internal stresses.

Polarization states of the ferroelectric film are shown in FIG. 3 in which the direction and magnitude of spontaneous polarization are indicated in the form of a vector. FIG. 3A shows the case where spontaneous polarizations of the ferroelectric film in the resonator portion and the spurious suppressing element portion are aligned in the same direction and different in magnitude from each other. FIG. 3B shows the case where spontaneous polarizations of the ferroelectric film in the resonator portion and the spurious suppressing element portion are aligned in opposite directions and identical in magnitude to each other.

### Second Embodiment

FIG. 4 is a view showing a second embodiment of the invention. The embodiment is different from the first embodiment shown in FIG. 1 in that a non-piezoelectric insulating film 41 is formed between the first wiring 9 or the second wiring 10 and the piezoelectric layer 6. The piezoelectric layer 6 has a function of exciting the elements by means of the piezoelectric effect, and also another effect of insulating the first wiring 9 and the second wiring 10 from the common electrode 5. In the structure of FIG. 1, also the piezoelectric layer in the portion of the first wiring 9 or the second wiring 10 excites, and hence oscillation of an extra mode occurs to cause spurious. Therefore, the non-piezoelectric insulating film 41 is formed between the first wiring 9 or the second wiring 10 and the piezoelectric layer 6, whereby the piezoelectric layer in the wiring portions can be prevented from exciting.

The non-piezoelectric insulating film 41 is requested to have characteristics that the dielectric constant is small, and that the acoustic impedance is low. As the dielectric constant of the non-piezoelectric insulating film 41 is smaller as compared with that of the piezoelectric layer 6, the voltage applied to the piezoelectric layer 6 is lower, and the non-piezoelectric insulating film 41 can be made thinner. The embodiment has an advantage that, as the acoustic impedance of the non-piezoelectric insulating film 41 is lower, leakage waves are smaller in magnitude. As the non-piezoelectric insulating film 41, for example, a material such as a silicon oxide, silicon nitride, a polyimide resin, or a polymer is preferably used. These materials have a dielectric constant of 3 to 10, and the PZT ferroelectric film has a dielectric constant of 400 to 2,000. When a silicon oxide, silicon nitride, a polyimide resin, or a polymer is stacked on the PZT film, therefore, the voltage to be applied to the portions of the PZT film in the wiring portions can be lowered very easily to one tenth or smaller.

### Third Embodiment

FIG. 5 is a view showing a third embodiment of the invention. The embodiment is different from the second embodiment shown in FIG. 4 in that an adhesive agent 51 is configured between the substrate and the multi-layered member formed thereon. The adhesive agent 51 has a low acoustic impedance, and hence exerts an effect that oscillations excited by the resonator 2 are prevented from leaking to the substrate.

### Fourth Embodiment

FIG. 6 is a view showing a fourth embodiment of the invention. The embodiment is different from the third embodiment shown in FIG. 5 in that the substrate 4 is partly recessed, and an air gap 61 is formed in the regions of the first and second electrodes 7 and 8. The air gap 61 exerts an effect that oscillations excited by the resonator 2 are prevented from leaking to the substrate.

### Fifth Embodiment

FIG. 7 is a view showing a fifth embodiment of the invention. The embodiment is different from the third embodiment shown in FIG. 5 in that a reflective layer 71 consisting of at least one layer having a thickness which is one fourth of the resonant wavelength is formed between the substrate and the common electrode. The reflective layer 71 exerts an effect that oscillations excited by the resonator 2 are prevented from leaking to the substrate.

### Sixth Embodiment

FIG. 8 is a view showing a sixth embodiment of the invention. A film bulk acoustic resonator circuit 81 is configured by the film bulk acoustic resonator 1, a communication signal generating section 82, and a spurious suppression signal generating section 83. One output end of the communication signal generating section 82 is connected to the common electrode 5, and the other output end is connected to the first wiring 9. One output end of the suppression signal generating section 83 is connected to the common electrode 5, and the other output end is connected to the second wiring 10. The suppression signal generating section 83 outputs a signal which can cancel spurious signals generated by the resonator 2, to excite the spurious suppressing element.

As described above, according to first aspect of the invention, the film bulk acoustic resonator of the invention is a film bulk acoustic resonator comprises: a piezoelectric element including a ferroelectric film; a first electrode which is disposed on a first surface of the piezoelectric element; a second electrode which is disposed on the first surface, which is electrically insulated from the first electrode, and which is disposed to extend along at least a part of an edge of the first electrode; a third electrode which is disposed on a second surface opposite to the first surface of the piezoelectric element, and which is opposed to the first and second electrodes across the piezoelectric element; a first wiring through which an electric power is supplied to the first electrode; and a second wiring through which an electric power is supplied to the second electrode, wherein a first region of the ferroelectric film which is interposed between the first and third electrodes has a first polarization state, and a second region of the ferroelectric film which is interposed between the second and third electrodes has a second polarization state that is different from the first polarization state. An acoustic impedance of a ferroelectric film largely depends on the direction and magnitude of polarization. When the spontaneous polarization of the ferroelectric film is controlled, therefore, the acoustic impedances of the piezoelectric element in the first and second regions can be more easily controlled than that in the conventional art. As a result, it is possible to provide a film bulk acoustic resonator which has excellent reflective properties and a stable effective band width, at a low cost with high reproducibility.

Additionally, a magnitude of spontaneous polarization in the first polarization state may be larger than a magnitude of spontaneous polarization in the second polarization state. Therefore, the acoustic impedance of the first region is larger than that of the second region. As a result of an electrical process, f1<f3<f2 can be easily attained.

Additionally, a direction of spontaneous polarization in the first polarization state is different from a direction of spontaneous polarization in the second polarization state. Therefore, f1<f3<f2 can be more easily attained.

Additionally, a non-piezoelectric insulating film may be formed between the first and second wirings, and the piezoelectric element. Therefore, it is possible to provide a film bulk acoustic resonator which has excellent reflective properties and a stable effective band width.

Additionally, the non-piezoelectric insulating film is made of a material which produces a low acoustic impedance, and which mainly contains at least silicon oxide, silicon nitride, a polyimide resin, or a polymer. Therefore, a piezoelectric layer of the first or second wiring portion can be prevented from exciting. It is possible to provide a film bulk acoustic resonator which has further excellent reflective properties and a stable effective band width.

Additionally, the ferroelectric thin film layer may be a PZT thin film which is preferentially oriented in (001) orientation, and a direction of a polarization axis coincides with a direction along which the electrodes are opposed to each other. Therefore, it is possible to provide a film bulk acoustic resonator in which the high electromechanical conversion efficiency is high, the crystallinity is uniform in the propagation direction of an acoustic wave, and hence the insertion loss is very small.

Additionally, the piezoelectric element further includes a temperature compensating layer, and the compensating layer is made of strontium titanate or a solid solution of strontium titanate and barium titanate. Therefore, the temperature coefficients of the dielectric constant and the sound velocity in the temperature compensating layer are different in polarity from those in the PZT. As a result, it is possible to provide a film bulk acoustic resonator in which the temperature coefficients of the dielectric constant and the sound velocity are very small.

Additionally, the first region has a function of a resonator, and the second region has a function of a spurious suppressing element. Therefore, it is possible to provide a film bulk acoustic resonator in which spurious signals can be suppressed more efficiently.

According to another aspect of the invention, a stacked film bulk acoustic resonator comprises: a multi-layered member, and a substrate on which the multi-layered member is to be mounted, the multi-layered member comprising: a piezoelectric element including a ferroelectric film; a first electrode which is disposed on a first surface of the piezoelectric element; a second electrode which is disposed on the first surface, which is electrically insulated from the first electrode, and which is disposed to extend along at least a part of an edge of the first electrode; a third electrode which is disposed on a second surface opposite to the first surface of the piezoelectric element, and which is opposed to the first and second electrodes across the piezoelectric element; a first wiring through which an electric power is supplied to the first electrode; and a second wiring through which an electric power is supplied to the second electrode, wherein a first region of the ferroelectric film which is interposed between the first and third electrodes has a first polarization state, and a second region of the ferroelectric film which is interposed between the second and third electrodes has a second polarization state. Therefore, the multi-layered member and the substrate can be separately produced, so that the production steps can be simplified.

Additionally, the multi-layered member and the substrate are bonded together by an adhesive material. Therefore, it is possible to provide a film bulk acoustic resonator in which waves can be further prevented from leaking from the multi-layered member to the substrate, and which has further excellent reflective properties and a stable effective band width. After the multi-layered member is formed on a certain substrate, the multi-layered member can be transferred onto another substrate via an adhesive agent. Therefore, an arbitrary substrate can be used, so that the production steps can be simplified and the cost of the substrate can be lowered.

Additionally, an air gap is formed between at least a part of the first and second regions, and the substrate. Therefore, it is possible to provide a film bulk acoustic resonator in which waves can be further prevented from leaking from the multi-layered member to the substrate, and which has further excellent reflective properties and a stable effective band width.

Additionally, a reflective layer is formed between at least a part of the first and second regions, and the substrate, the reflective layer having a thickness which is about one fourth of a resonant wavelength in the first region. Therefore, it is possible to provide a film bulk acoustic resonator in which waves can be further prevented from leaking from the multi-layered member to the substrate, and which has further excellent reflective properties and a stable effective band width.

According to another aspect of the invention, a film bulk acoustic resonator comprises: a ferroelectric film; a first electrode which is disposed on a first surface of the ferroelectric film; a second electrode which is disposed on the first surface, which is electrically insulated from the first electrode, and which is disposed to extend along at least a part of an edge of the first electrode; a third electrode which is disposed on a second surface opposite to the first surface of the ferroelectric film, and which is opposed to the first electrode across the ferroelectric film; a fourth electrode which is disposed on the second surface opposite to the first surface of the ferroelectric film, and which is opposed to the second electrode across the ferroelectric film; a first wiring which is connected to one of the first and third electrodes to generate a potential difference between the first and third electrodes; and a second wiring which is connected to one of the second and fourth electrodes to generate a potential difference between the second and fourth electrodes, wherein a first region of the ferroelectric film which is interposed between the first and third electrodes has a first polarization state, and a second region of the ferroelectric film which is interposed between the second and fourth electrodes has a second polarization state. Therefore, spurious suppression can be conducted more adequately.

According to another aspect of the invention, a film bulk acoustic resonator in which in which a multi-layered member is placed on a substrate, the multi-layered member comprising: a common electrode; a piezoelectric layer formed on the common electrode; a first electrode which is formed on the piezoelectric layer, and which is used for a resonator; a second electrode which surrounds an edge of the first electrode with forming a gap therebetween, and which is used for a spurious suppressing element; a first wiring through which an electric power is supplied to the first electrode; and a second wiring through which an electric power is supplied to the second electrode, wherein the piezoelectric layer includes a ferroelectric film, and a polarization state of the ferroelectric film corresponding to the resonator is different from a polarization state of the ferroelectric film corresponding to the spurious suppressing element. Therefore, the spontaneous polarization state of the ferroelectric film can be controlled, and hence the acoustic impedance of the piezoelectric element in the first and second regions can be more easily controlled than that in the conventional art. As a result, it is possible to provide a film bulk acoustic resonator which has excellent reflective properties and a stable effective band width, at a low cost with high reproducibility. After the multi-layered member is formed on a certain substrate, the multi-layered member can be transferred onto another substrate via an adhesive agent. Therefore, an arbitrary substrate can be used, so that the production steps can be simplified and the cost of the substrate can be lowered.

Furthermore, the invention provides a film bulk acoustic resonator circuit comprising: a film bulk acoustic resonator as mentioned above; a communication signal generating section which outputs a signal through the first wiring; and a spurious suppression signal generating section which outputs a signal through the second wiring. According to the configuration, a spurious suppression device portion and a resonator portion are independently excited, and leakage waves from the resonator are cancelled. Therefore, the spurious suppression signal generating section can control the voltage, phase, and frequency of a spurious suppression signal so as to suppress generation of spurious signals. Consequently, it is possible to provide a film bulk acoustic resonator circuit which has excellent reflective properties and a stable effective band width.

Moreover, the invention provides a transceiver wherein a film bulk acoustic resonator or a film bulk acoustic resonator circuit as mentioned above is used. It is possible to provide a duplexer having filter characteristics which are sufficiently steep to enable the duplexer to be used in applications such as a CDMA PCS device and the like as well as a filter.

As described above, according to one film bulk acoustic resonator of the invention, the piezoelectric layer includes a ferroelectric film, and the polarization state of the ferroelectric film in the first region is different from that in the second region, whereby the acoustic impedances of the first and second regions can be easily controlled. Therefore, both the performance improvement and the cost reduction can be attained.

The present disclosure relates to subject matter contained in priority Japanese Patent Application No. 2003-097900 filed on Apr. 1, 2003, the content of which is herein expressly incorporated by reference in its entirety.

1. A film bulk acoustic resonator comprising:
a piezoelectric element including a ferroelectric film;
a first electrode which is disposed on a first surface of said piezoelectric element;
a second electrode which is disposed on said first surface, which is electrically insulated from said first electrode, and which is disposed to extend along at least a part of an edge of said first electrode;
a third electrode which is disposed on a second surface opposite to said first surface of said piezoelectric element, and which is opposed to said first and second electrodes across said piezoelectric element;
a first wiring through which an electric power is supplied to said first electrode; and
a second wiring through which an electric power is supplied to said second electrode,
wherein a first region of said ferroelectric film which is interposed between said first and third electrodes has a first polarization state, and a second region of said ferroelectric film which is interposed between said second and third electrodes has a second polarization state that is different from the first polarization state.

2. A film bulk acoustic resonator according to claim 1, wherein a magnitude of spontaneous polarization in the first polarization state is larger than a magnitude of spontaneous polarization in the second polarization state.

3. A film bulk acoustic resonator according to claim 1, wherein a direction of spontaneous polarization in the first polarization state is different from a direction of spontaneous polarization in the second polarization state.

4. A film bulk acoustic resonator according to claim 3, wherein the direction of spontaneous polarization in the first polarization state is opposite to the direction of spontaneous polarization in the second polarization state.

5. A film bulk acoustic resonator according to claim 1, wherein a non-piezoelectric insulating film is formed between said first and second wirings, and said piezoelectric element.

6. A film bulk acoustic resonator according to claim 4, wherein said non-piezoelectric insulating film mainly contains at least silicon oxide, silicon nitride, a polyimide resin, or a polymer.

7. A film bulk acoustic resonator according to claim 1, wherein said ferroelectric film includes a PZT thin film which is preferentially oriented in (001) orientation.

8. A film bulk acoustic resonator according to claim 6, wherein said piezoelectric element further includes a temperature compensating layer, and said temperature compensating layer mainly contains strontium titanate or a solid solution of strontium titanate and barium titanate.

9. A film bulk acoustic resonator according to claim 1, wherein said first region has a function of a resonator, and said second region has a function of a spurious suppressing element.

10. A film bulk acoustic resonator comprising:
a multi-layered member, and
a substrate on which said multi-layered member is to be mounted,
said multi-layered member comprising:
a piezoelectric element including a ferroelectric film;
a first electrode which is disposed on a first surface of said piezoelectric element;
a second electrode which is disposed on said first surface, which is electrically insulated from said first electrode, and which is disposed to extend along at least a part of an edge of said first electrode;
a third electrode which is disposed on a second surface opposite to said first surface of said piezoelectric element, and which is opposed to said first and second electrodes across said piezoelectric element;
a first wiring through which an electric power is supplied to said first electrode; and
a second wiring through which an electric power is supplied to said second electrode,
wherein a first region of said ferroelectric film which is interposed between said first and third electrodes has a first polarization state, and a second region of said ferroelectric film which is interposed between said second and third electrodes has a second polarization state.

11. A film bulk acoustic resonator according to claim 10, wherein said multi-layered member and said substrate are bonded together by an adhesive material.

12. A film bulk acoustic resonator according to claim 10, wherein an air gap is formed between at least a part of said first and second regions, and said substrate.

13. A film bulk acoustic resonator according to claim 10, wherein a reflective layer is formed between at least a part of said first and second regions, and said substrate, said reflective layer having a thickness which is one fourth of a resonant wavelength in said first region.

14. A film bulk acoustic resonator comprising:
a ferroelectric film;
a first electrode which is disposed on a first surface of said ferroelectric film;
a second electrode which is disposed on said first surface, which is electrically insulated from said first electrode, and which is disposed to extend along at least a part of an edge of said first electrode;
a third electrode which is disposed on a second surface opposite to said first surface of said ferroelectric film, and which is opposed to said first electrode across said ferroelectric film;
a fourth electrode which is disposed on said second surface opposite to said first surface of said ferroelectric film, and which is opposed to said second electrode across said ferroelectric film;
a first wiring which is connected to one of said first and third electrodes to generate a potential difference between said first and third electrodes; and
a second wiring which is connected to one of said second and fourth electrodes to generate a potential difference between said second and fourth electrodes,
wherein a first region of said ferroelectric film which is interposed between said first and third electrodes has a first polarization state, and a second region of said ferroelectric film which is interposed between said second and fourth electrodes has a second polarization state.

15. A film bulk acoustic resonator in which a multi-layered member is placed on a substrate, said multi-layered member comprising:
a common electrode;
a piezoelectric layer formed on said common electrode;
a first electrode which is formed on said piezoelectric layer, and which is used for a resonator;
a second electrode which surrounds an edge of said first electrode with forming a gap therebetween, and which is used for a spurious suppressing element;
a first wiring through which an electric power is supplied to said first electrode; and
a second wiring through which an electric power is supplied to said second electrode,
wherein said piezoelectric layer includes a ferroelectric film, and a polarization state of said ferroelectric film corresponding to said resonator is different from a polarization state of said ferroelectric film corresponding to said spurious suppressing element.

16. A film bulk acoustic resonator circuit comprising:
a film bulk acoustic resonator according to claim 1;
a communication signal generating section which outputs a signal through said first wiring; and
a spurious suppression signal generating section which outputs a signal through said second wiring.

17. A transceiver wherein a film bulk acoustic resonator or a film bulk acoustic resonator circuit according to claim 1 is used.

18. A film bulk acoustic resonator circuit comprising:
a film bulk acoustic resonator according to claim 2;
a communication signal generating section which outputs a signal through said first wiring; and
a spurious suppression signal generating section which outputs a signal through said second wiring.

19. A film bulk acoustic resonator circuit comprising:
a film bulk acoustic resonator according to claim 3;
a communication signal generating section which outputs a signal through said first wiring; and
a spurious suppression signal generating section which outputs a signal through said second wiring.

20. A film bulk acoustic resonator circuit comprising:
a film bulk acoustic resonator according to claim 4;
a communication signal generating section which outputs a signal through said first wiring; and
a spurious suppression signal generating section which outputs a signal through said second wiring.

21. A film bulk acoustic resonator circuit comprising:
a film bulk acoustic resonator according to claim 5;
a communication signal generating section which outputs a signal through said first wiring; and
a spurious suppression signal generating section which outputs a signal through said second wiring.

22. A film bulk acoustic resonator circuit comprising:
a film bulk acoustic resonator according to claim 6;
a communication signal generating section which outputs a signal through said first wiring; and
a spurious suppression signal generating section which outputs a signal through said second wiring.

23. A film bulk acoustic resonator circuit comprising:
a film bulk acoustic resonator according to claim 7;
a communication signal generating section which outputs a signal through said first wiring; and
a spurious suppression signal generating section which outputs a signal through said second wiring.

24. A film bulk acoustic resonator circuit comprising:
a film bulk acoustic resonator according to claim 8;
a communication signal generating section which outputs a signal through said first wiring; and
a spurious suppression signal generating section which outputs a signal through said second wiring.

25. A film bulk acoustic resonator circuit comprising:
a film bulk acoustic resonator according to claim 9;
a communication signal generating section which outputs a signal through said first wiring; and
a spurious suppression signal generating section which outputs a signal through said second wiring.

26. A film bulk acoustic resonator circuit comprising:
a film bulk acoustic resonator according to claim 10;
a communication signal generating section which outputs a signal through said first wiring; and
a spurious suppression signal generating section which outputs a signal through said second wiring.

27. A film bulk acoustic resonator circuit comprising:
a film bulk acoustic resonator according to claim 11;
a communication signal generating section which outputs a signal through said first wiring; and
a spurious suppression signal generating section which outputs a signal through said second wiring.

28. A film bulk acoustic resonator circuit comprising:
a film bulk acoustic resonator according to claim 12;
a communication signal generating section which outputs a signal through said first wiring; and
a spurious suppression signal generating section which outputs a signal through said second wiring.

29. A film bulk acoustic resonator circuit comprising:
a film bulk acoustic resonator according to claim 13;
a communication signal generating section which outputs a signal through said first wiring; and
a spurious suppression signal generating section which outputs a signal through said second wiring.

30. A film bulk acoustic resonator circuit comprising:
a film bulk acoustic resonator according to claim 14;
a communication signal generating section which outputs a signal through said first wiring; and
a spurious suppression signal generating section which outputs a signal through said second wiring.

31. A film bulk acoustic resonator circuit comprising:
a film bulk acoustic resonator according to claim 15;
a communication signal generating section which outputs a signal through said first wiring; and
a spurious suppression signal generating section which outputs a signal through said second wiring.

32. A transceiver wherein a film bulk acoustic resonator or a film bulk acoustic resonator circuit according to claim 2 is used.

33. A transceiver wherein a film bulk acoustic resonator or a film bulk acoustic resonator circuit according to claim 3 is used.

34. A transceiver wherein a film bulk acoustic resonator or a film bulk acoustic resonator circuit according to claim 4 is used.

35. A transceiver wherein a film bulk acoustic resonator or a film bulk acoustic resonator circuit according to claim 5 is used.

36. A transceiver wherein a film bulk acoustic resonator or a film bulk acoustic resonator circuit according to claim 6 is used.

37. A transceiver wherein a film bulk acoustic resonator or a film bulk acoustic resonator circuit according to claim 7 is used.

38. A transceiver wherein a film bulk acoustic resonator or a film bulk acoustic resonator circuit according to claim 8 is used.

39. A transceiver wherein a film bulk acoustic resonator or a film bulk acoustic resonator circuit according to claim 9 is used.

40. A transceiver wherein a film bulk acoustic resonator or a film bulk acoustic resonator circuit according to claim 10 is used.

41. A transceiver wherein a film bulk acoustic resonator or a film bulk acoustic resonator circuit according to claim 11 is used.

42. A transceiver wherein a film bulk acoustic resonator or a film bulk acoustic resonator circuit according to claim 12 is used.

43. A transceiver wherein a film bulk acoustic resonator or a film bulk acoustic resonator circuit according to claim 13 is used.

44. A transceiver wherein a film bulk acoustic resonator or a film bulk acoustic resonator circuit according to claim 14 is used.

45. A transceiver wherein a film bulk acoustic resonator or a film bulk acoustic resonator circuit according to claim 15 is used.

46. A transceiver wherein a film bulk acoustic resonator or a film bulk acoustic resonator circuit according to claim 16 is used.
